(19) United States
(12) Patent Application Publication
(10) Pub. No.: US 2009/0208854 A1
(43) Pub. Date: Aug. 20, 2009

(54) Photosensitive Resin Composition for Forming Column Spacer of Liquid Crystal Display, Method for Forming Column Spacer Using the Composition, Column Spacer Formed by the Method, and Display Device Comprising the Column Spacer

(75) Inventors: Jung Sik CHOI, Seoul (KR); Jae Sun HAN, Suwon (KR); Jeong Min HONG, Suseong-gu (KR); Kil Sung LEE, Gwacheon (KR)

Correspondence Address: SUMMA, ADDITON & ASHE, P.A., 11610 NORTH COMMUNITY HOUSE ROAD, SUITE 200, CHARLOTTE, NC, 28277, US

(73) Assignee: Cheil Industries Inc., Gumi-si (KR)

(21) Appl. No.: 12/430,519

(22) Filed: Apr. 27, 2009

Related U.S. Application Data
(63) Continuation-in-part of application No. PCT/KR2006/005556, filed on Dec. 19, 2006.

(30) Foreign Application Priority Data
Nov. 17, 2006 (KR) 10-2006-0114021

(51) Int. Cl. G03F 7/004; G03F 7/20

(52) U.S. Cl. 430/9; 430/280.1; 430/285.1; 430/325

(57) ABSTRACT

Disclosed is a photosensitive resin composition used to form spacers of a liquid crystal display device. The photosensitive resin composition comprises [A] an alkali-soluble resin, [B] a reactive unsaturated compound, [C] a photopolymerization initiator and [D] a solvent wherein the alkali-soluble resin [A] is a copolymer including structural units represented by Formulae 1 to 3, which are described in the specification. Column spacers formed using the photosensitive resin composition exhibit high compressive displacement, elastic recovery and residual film ratio.

### CROSS-REFERENCE TO RELATED APPLICATIONS

This non-provisional application is a continuation-in-part application of PCT Application No. PCT/KR2006/005556, filed Dec. 19, 2006, pending, which designates the U.S. and is hereby incorporated by reference in its entirety, and claims priority therefrom under 35 USC Section 120. This application also claims priority under 35 USC Section 119 from Korean Patent Application No. 10-2006-0114021, filed Nov. 17, 2006, the entire disclosure of which is also hereby incorporated by reference.

### FIELD OF THE INVENTION

The present invention relates to a photosensitive resin composition for forming column spacers of a liquid crystal display device, and more specifically to a photosensitive resin composition for forming column spacers of a liquid crystal display device that exhibit excellent processing stability, high compressive displacement and high elastic recovery.

### BACKGROUND OF THE INVENTION

Liquid crystal display devices can use spherical or cylindrical silica or plastic beads to maintain a constant distance between upper and lower panels. Since the beads are randomly distributed on and applied to a glass substrate, they may be positioned within active pixels. In this case, the opening ratio of the liquid crystal display device is decreased. Further, the contrast ratio of the liquid crystal display device is lowered due to light leakage (a phenomenon in which light is emitted in directions other than the forward direction).

To solve these problems, a method for the formation of spacers by photolithography has been introduced. According to this method, spacers can be formed by applying a photosensitive resin composition to a glass substrate, irradiating the photosensitive resin composition with UV light through a patterned mask, and developing the exposed photosensitive resin to form the spacers on portions of the glass substrate other than within active pixels. The spacers thus formed have a pattern corresponding to the pattern of the mask. However, if the spacers have poor processing stability, low compressive displacement and low compressive recovery, a layer underlying R, G and B pixels of a color filter of a liquid crystal display device can be abnormally deformed, which can result in the formation of gap defects between or within the respective pixels. This problem leads to defects in color or contrast, which can deteriorate the quality of display images. Further, if the spacers have a low compressive recovery, vacuum voids are formed, which can also deteriorate the quality of display images.

Various attempts to solve these problems have been made. For example, Korean Patent No. 10-0268697, which has been regarded as the best method to solve the above-mentioned problems, teaches the use of a copolymer comprising a conjugated diolefin-based unsaturated compound as a binder resin to achieve improved compressive displacement and elastic recovery.

However, synthesis of copolymers including 1,3-butadiene as a structural unit, which is mainly used to increase the elastic recovery, requires the use of a high-pressure reactor and has a disadvantage in that it is difficult to control the content of 1,3-butadiene due to the low reactivity of 1,3-butadiene. Thus, there still remains a strong need to develop a binder that exhibits characteristics comparable to copolymers using 1,3-butadiene and is easy to supply for its synthesis with minimal or no difficulty.

### SUMMARY OF THE INVENTION

The present invention provides a photosensitive resin composition for forming column spacers of a liquid crystal display device that can exhibit excellent processing stability, high compressive displacement and high elastic recovery. According to the present invention, the photosensitive resin composition for forming column spacers of a liquid crystal display device comprises [A] an alkali-soluble resin, [B] a reactive unsaturated compound, [C] a photopolymerization initiator and [D] a solvent wherein the alkali-soluble resin [A] is a copolymer including structural units represented by Formulae 1 to 3:

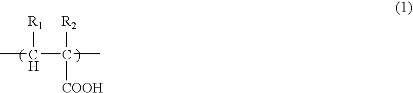

wherein R₁ and R₂ are each independently a hydrogen atom or a C₁-C₆ alkyl group;

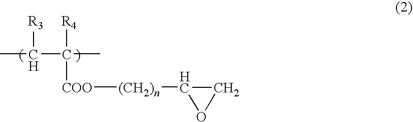

wherein R₃ and R₄ are each independently a hydrogen atom or a C₁-C₆ alkyl group and n is an integer from 1 to 10; and

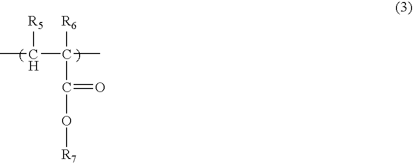

wherein R₅ and R₆ are each independently a hydrogen atom or a C₁-C₆ alkyl group and R₇ is a linear or branched C₆-C₃₀ alkyl group.

According to the present invention, there are also provided column spacers of a liquid crystal display device formed using the photosensitive resin composition. The present invention further provides a liquid crystal display device using the column spacers.

According to the present invention, spacers of a liquid crystal display device formed using the photosensitive resin composition can be used to maintain a uniform cell gap, irrespective of the size of the liquid crystal display device, and to prevent variations in cell gap arising from movement or vibration of liquid crystal panels or impact on liquid crystal panels. Particularly, since spacers formed using the photosensitive resin composition exhibit very high compressive displacement and elastic recovery, liquid crystal display devices employing the spacers can protect the spacers and underlying structures from being destroyed by an externally applied impact.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a diagram showing deformation of a column spacer when a force is applied to the column spacer; and

FIG. 2 is a graph showing a relationship between the compressive displacement and the recovery of a column spacer.

### DETAILED DESCRIPTION OF THE INVENTION

The present invention now will be described more fully hereinafter in the following detailed description of the invention, in which some, but not all embodiments of the invention are described. Indeed, this invention may be embodied in many different forms and should not be construed as limited to the embodiments set forth herein; rather, these embodiments are provided so that this disclosure will satisfy applicable legal requirements.

### Alkali-Soluble Resin [A]

The alkali-soluble resin [A] used in the present invention is a copolymer including the following structural units:

(a) a structural unit represented by Formula 1:

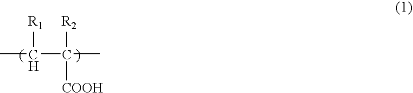

wherein R₁ and R₂ are each independently a hydrogen atom or a C₁-C₆ alkyl group;
(b) a structural unit represented by Formula 2:

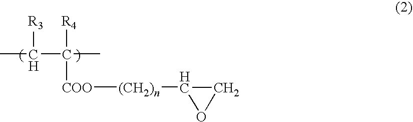

wherein R₃ and R₄ are each independently a hydrogen atom or a C₁-C₆ alkyl group and n is an integer from 1 to 10; and
(c) a structural unit having a long-chain alkyl group represented by Formula 3:

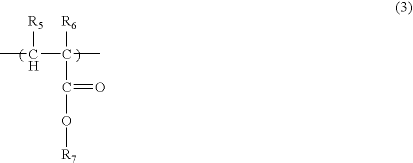

wherein R₅ and R₆ are each independently a hydrogen atom or a C₁-C₆ alkyl group and R₇ is a linear or branched C₆-C₃₀ alkyl group.

The copolymer may be a random copolymer, an alternating copolymer, a block copolymer, or a graft copolymer.

The structural unit of Formula 1 may be derived from at least one carboxylic acid compound such as but not limited to acrylic acid, methacrylic acid, ethacrylic acid, crotonic acid, 2-pentenoic acid, and the like, and combinations thereof. Acrylic acid and methacrylic acid can exhibit high copolymerization reactivity, excellent heat resistance and are readily commercially available.

The alkali soluble resin includes the structural unit of Formula 1 in an amount of about 5 to about 50% by weight, for example about 10 to about 40% by weight, based on the total weight of the alkali-soluble resin. When the structural unit of Formula 1 is included in an amount of less than about 5% by weight, the solubility of the alkali-soluble resin in an aqueous alkaline solution tends to decrease, leaving residue in the solution. Meanwhile, when the structural unit of Formula 1 is included in an amount of more than about 50% by weight, the solubility of the alkali-soluble resin in an aqueous alkaline solution can excessively increase, making it difficult to form a pattern.

The structural unit of Formula 2 may be derived from at least one epoxy compound such as but not limited to epoxyalkyl acrylates, such as glycidyl acrylate, 2-methylglycidyl acrylate, 3,4-epoxybutyl acrylate, 6,7-epoxyheptyl acrylate and 3,4-epoxycyclohexyl acrylate; epoxyalkyl methacrylates, such as glycidyl methacrylate, 2-methylglycidyl methacrylate, 3,4-epoxybutyl methacrylate, 6,7-epoxyheptyl methacrylate and 3,4-epoxycyclohexyl methacrylate; epoxyalkyl α-alkylacrylates, such as glycidyl α-ethylacrylate, glycidyl α-n-propylacrylate, glycidyl α-n-butylacrylate and 6,7-epoxyheptyl α-ethylacrylate; and glycidyl ethers, such as o-vinylbenzyl glycidyl ether, m-vinylbenzyl glycidyl ether and p-vinylbenzyl glycidyl ether; and the like, and combinations thereof. Glycidyl methacrylate, 2-methylglycidyl methacrylate, 6,7-epoxyheptyl methacrylate, o-vinylbenzyl glycidyl ether, m-vinylbenzyl glycidyl ether and p-vinylbenzyl glycidyl can exhibit high copolymerization reactivity and impart high strength to spacers formed using the photosensitive resin composition.

The alkali soluble resin includes the structural unit of Formula 2 in an amount of about 10 to about 70% by weight, for example about 20 to about 60% by weight, based on the total weight of the alkali-soluble resin. When the structural unit of Formula 2 is included in an amount of less than about 10% by weight, the strength of spacers to be formed tends to be lowered. Meanwhile, when the structural unit of Formula 2 is included in an amount of more than about 70% by weight, the copolymer can have poor storage stability.

The structural unit having a long-chain alkyl group represented by Formula 3 is included in the alkali-soluble resin to improve the weather resistance, low shrinkage upon heating and elastic recovery of spacers to be formed. The structural unit having a long-chain alkyl group may be derived from at least one compound such as but not limited to alkyl esters, such as n-hexyl methacrylate, isodecyl methacrylate, lauryl methacrylate and stearyl methacrylate; branched alkyl esters, such as 2-ethylhexyl methacrylate; and the like, and combinations thereof.

The alkali soluble resin includes the structural unit having a long-chain alkyl group represented by Formula 3 in an amount of about 0.1 to about 30% by weight, for example about 1 to about 15% by weight, based on the total weight of the alkali-soluble resin. When the structural unit of Formula 3 is included in an amount of less than about 0.1% by weight, the binder can be softened, and as a result, the elastic recovery of spacers to be formed is liable to be deteriorated or the shrinkage of spacers to be formed upon thermal curing is liable to be increased. Meanwhile, when the structural unit of Formula 3 is included in an amount of more than about 30% by weight, the binder can become hard, and as a result, the compressive displacement of spacers to be formed tends to be lowered.

In order to control the molecular weight of the alkali-soluble resin and to achieve improved strength and residual film ratio of spacers to be formed, the alkali-soluble resin may optionally include a structural unit represented by Formula 4 or 5 or a combination thereof:

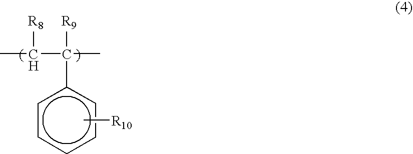

wherein R₈ and R₉ are each independently a hydrogen atom or a C₁-C₆ alkyl group and R₁₀ is a hydrogen atom, a C₁-C₄ alkyl group or a C₁-C₄ alkoxy group; or

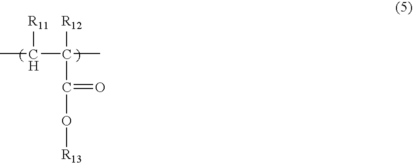

wherein R₁₁ and R₁₂ are each independently a hydrogen atom or a methyl group, and R₁₃ is a C₁-C₅ alkyl group or a C₅-C₁₂ cycloalkyl group which may be unsubstituted or substituted with one or more methyl groups, C₁-C₄ oxyalkyl groups, or a combination thereof.

The structural unit of Formula 4 or 5 may be derived from at least one monoolefinic compound such as but not limited to alkyl methacrylates, such as methyl methacrylate, ethyl methacrylate, n-butyl methacrylate, sec-butyl methacrylate and t-butyl methacrylate; alkyl acrylates, such as methyl acrylate and isopropyl acrylate; cycloalkyl methacrylates, such as cyclohexyl methacrylate, 2-methylcyclohexyl methacrylate, 2-methylcyclohexyl acrylate, dicyclopentanyl methacrylate, dicyclopentanyloxyethyl methacrylate and isobornyl methacrylate; cycloalkyl acrylates, such as cyclohexyl acrylate, dicyclopentanyl acrylate, dicyclopentaoxyethyl acrylate and isobornyl acrylate; aryl acrylates, such as phenyl acrylate and benzyl acrylate; aryl methacrylates, such as phenyl methacrylate and benzyl methacrylate; dicarboxylic acid diesters, such as diethyl maleate, diethyl fumarate and diethyl itaconate; hydroxyalkyl esters, such as 2-hydroxyethyl methacrylate and 2-hydroxypropyl methacrylate; styrenes, such as styrene, α-methylstyrene, m-methylstyrene, p-methylstyrene, vinyltoluene, p-methoxystyrene and p-t-butoxystyrene; and the like, and combinations thereof.

The alkali soluble resin includes the structural unit of Formula 4 or 5 or both in an amount of about 10 to about 70% by weight, for example about 20 to about 50% by weight, based on the total weight of the alkali-soluble resin.

The alkali-soluble resin can be prepared by a copolymerization process alone without undergoing any modification. The alkali-soluble resin can be prepared by radical-polymerizing the structural units in a solvent in the presence of a catalyst (e.g., a polymerization initiator).

Examples of the solvent used herein include without limitation alcohols, such as methanol and ethanol; ethers, such as tetrahydrofuran; cellosolve esters, such as methyl cellosolve acetate; propylene glycol alkyl ether acetates, such as propylene glycol methyl ether acetate and propylene glycol propyl ether acetate; aromatic hydrocarbons; ketones; esters; and the like, and combinations thereof. The solvent may be the same as that used in the photosensitive resin composition of the present invention.

The catalyst used for the radical polymerization may be a common radical polymerization catalyst. Examples of suitable radical polymerization catalysts include without limitation azo compounds, such as 2,2-azobisisobutyronitrile, 2,2-azobis-(2,4-dimethylvaleronitrile) and 2,2-azobis-(4-methoxy-2,4-dimethylvaleronitrile); organic peroxides, such as benzoyl peroxide, lauroyl peroxide, t-butylperoxypivalate and 1,1′-bis-(t-butylperoxy)cyclohexane; hydrogen peroxide; and the like, and combinations thereof. When a peroxide is used as the radical polymerization initiator, a combination of the peroxide with a reducing agent may be used as a redox initiator.

The molecular weight and the molecular weight distribution of the copolymer are not particularly limited so long as the composition of the present invention can be uniformly applied.

The photosensitive resin composition includes the alkali-soluble resin in an amount of about 1 to about 50% by weight, for example about 3 to about 30% by weight, in terms of the solid content of the alkali-soluble resin, based on the total weight of the composition. When the content of the alkali-soluble resin is lower than about 1% by weight, a pattern may not be readily formed. Meanwhile, when the content of the alkali-soluble resin is higher than about 50% by weight, the composition can be highly viscous, resulting in poor processability, and development of the composition may be insufficient, leaving residue behind.

### Reactive Unsaturated Compound [B]

The reactive unsaturated compound can be a monomer or oligomer that is generally used in photosensitive resin compositions, such as but not limited to a monofunctional or polyfunctional ester of an acrylic or methacrylic acid having at least one ethylenically unsaturated double bond.

Examples of such monofunctional (meth)acrylates include without limitation commercially available products, such as Alonix M-101, Alonix M-111 and Alonix M-114 (Toa Gosei Chem. Ind. Co.), AKAYARAD TC-110S and AKAYARAD TC-120S (Nippon Kayaku Co., Ltd.), and V-158 and V-2311 (Osaka Organic Chemical Ind. Ltd.). Examples of such difunctional (meth)acrylates include without limitation commercially available products, such as Aronix M-210, Aronix M-240 and Aronix M-6200 (Toa Gosei Chem. Ind. Co.), KAYARAD HDDA, KAYARAD HX-220 and KAYARAD R-604 (Nippon Kayaku Co., Ltd.), and V260, V313 and V335 HP (Osaka Organic Chemical Ind. Ltd.). Examples of such trifunctional or higher (meth)acrylates include without limitation trimethylolpropane triacrylate, pentaerythritol triacrylate, trisacryloyloxyethyl phosphate, pentaerythritol tetraacrylate, dipentaerythritol pentaacrylate, and dipentaerythritol hexaacrylate. These trifunctional or higher (meth)acrylates are commercially available, for example, Aronix M-309, Aronix M-400, Aronix M-405, Aronix M-450, Aronix M-7100, Aronix M-8030 and Aronix M-8060 (Toa Gosei Chem. Ind. Co.), KAYARAD TMPTA, KAYARAD DPCA-20, KAYARAD DPCA-30, KAYARAD DPCA-60 and KAYARAD DPCA-120 (Nippon Kayaku Co., Ltd.) and V-295, V-300, V-360, V-GPT, V-3PA and V-400 (Osaka Organic Chemical Ind. Ltd.). The above-mentioned compounds may be used alone or in combination.

The photosensitive resin composition includes the reactive unsaturated compound in an amount of about 1 to about 50% by weight, for example about 3 to about 30% by weight, based on the total weight of the composition. When the content of the reactive unsaturated compound is lower than about 1% by weight, the sensitivity of the reactive unsaturated compound in the presence of oxygen is liable to be deteriorated. When the content of the reactive unsaturated compound is higher than about 50% by weight, the compatibility of the reactive unsaturated compound with the copolymer is liable to drop and the surface of a coating film to be formed may be rough.

### Photopolymerization Initiator [C]

The photopolymerization initiator (C) used in the photosensitive resin composition of the present invention may be a radical or cationic photopolymerization initiator.

The photopolymerization initiator must be used taking into consideration exposure conditions (irrespective of the presence or absence of oxygen). Specifically, when the exposure is performed in the absence of oxygen, any kind of initiator selected from general radical photopolymerization initiators and cationic photopolymerization initiators may be used as the photopolymerization initiator.

Examples of such radical photopolymerization initiators include without limitation α-diketones, such as benzyl and diacetyl; acyloins, such as benzoin; acyloin ethers, such as benzoin methyl ether, benzoin ethyl ether and benzoin isopropyl ether; benzophenones, such as thioxanthone, 2,4-diethylthioxanthone, thioxanthone-4-sulfonic acid, benzophenone, 4,4′-bis(dimethylamino)benzophenone and 4,4′-bis(diethylamino)benzophenone; acetophenones, such as acetophenone, p-dimethylaminoacetophenone, α,α′-dimethoxyacetoxybenzophenone, 2,2′-dimethoxy-2-phenylacetophenone, p-methoxyacetophenone, 2-methyl-[4-(methylthlo)phenyl]-2-morpholino-1-propane and 2-benzyl-2-diemthylamino-1-(4-morpholinophenyl)-butan-1-one; quinones, such as anthraquinone and 1,4-naphthoquinone; halogen compounds, such as phenacyl chloride, tribromomethylphenylsulfone and tris(trichloromethyl)-s-triazine; peroxides, such as di-t-butyl peroxide; acylphosphine oxides, such as 2,4,6-trimethylbenzoyldiphenylphosphine oxide; and the like, and combinations thereof.

Examples of such cationic photopolymerization initiators include without limitation the following commercially available products: Adeca Ultraset PP-33 (Asahi Denka Kogyo K. K.) as a diazonium salt, OPTOMER SP-150.170 (Asahi Denka Kogyo K. K.) as a sulfonium salt, IRGACURE 261 (Ciba Geigy) as a metallocene compound, and the like, and combinations thereof.

When the exposure is performed in the presence of oxygen, the photosensitivity of some radical photopolymerization initiators drops, and as a result, the residual film ratio and hardness of exposed portions may be insufficient. When the exposure is performed in the presence of oxygen, (1) any cationic photopolymerization initiators may be used because there is no substantial decrease in the sensitivity of active species by oxygen and (2) some radical photopolymerization initiators can be used, including acetophenones, e.g., 2-methyl-[4-(methylthio)phenyl]-2-morpholino-1-propane and 2-benzyl-2-dimethylamino-1-(4-morpholinophenyl)-1-butan-1-one, halogen compounds, e.g., phenacyl chloride, tribromomethylphenylsulfone and tris(trichloromethyl)-s-triazine, and acylphosphine oxides, such as 2,4,6-trimethylbenzoyldiphenylphosphine oxide.

The photosensitive resin composition includes the photopolymerization initiator in an amount of about 0.1 to about 15% by weight, for example about 1 to about 10% by weight, based on the total weight of the composition. When the content of the photopolymerization initiator is lower than about 0.1% by weight, the sensitivity of radicals tends to drop due to the presence of oxygen. Meanwhile, when the content of the photopolymerization initiator is higher than about 15% by weight, the color density of the solution can be increased or the photopolymerization initiator may settle.

The radical photopolymerization initiator and the cationic photopolymerization initiator absorb light to be excited and deliver the excitation energy. Accordingly, the photopolymerization initiators may be used in combination with a photosensitizer causing a chemical reaction.

### Solvent [D]

The organic solvent used in the present invention is selected from organic solvents that are compatible and unreactive with the copolymer.

Examples of such organic solvents include without limitation: alcohols, such as methanol and ethanol; ethers, such as dichloroethyl ether, n-butyl ether, diisoamyl ether, methylphenyl ether and tetrahydrofuran; glycol ethers, such as ethylene glycol monomethyl ether and ethylene glycol monoethyl ether; cellosolve acetates, such as methyl cellosolve acetate, ethyl cellosolve acetate and diethyl cellosolve acetate; carbitols, such as methyl ethyl carbitol, diethyl carbitol, diethylene glycol monomethyl ether, diethylene glycol monoethyl ether, diethylene glycol dimethyl ether, diethylene glycol methyl ethyl ether and diethylene glycol diethyl ether; propylene glycol alkyl ether acetates, such as propylene glycol methyl ether acetate and propylene glycol propyl ether acetate; aromatic hydrocarbons, such as toluene and xylene; ketones, such as methyl ethyl ketone, cyclohexanone, 4-hydroxy-4-methyl-2-pentanone, methyl-n-propyl ketone, methyl-n-butyl ketone, methyl-n-amyl ketone and 2-heptanone; saturated aliphatic monocarboxylic acid alkyl esters, such as ethyl acetate, n-butyl acetate and isobutyl acetate; lactates, such as methyl lactate and ethyl lactate; alkyl oxyacetates, such as methyl oxyacetate, ethyl oxyacetate and butyl oxyacetate; alkyl alkoxyacetates, such as methyl methoxyacetate, ethyl methoxyacetate, butyl methoxyacetate, methyl ethoxyacetate and ethyl ethoxyacetate; alkyl 3-oxypropionates, such as methyl 3-oxypropionate and ethyl 3-oxypropionate; alkyl 3-alkoxypropionates, such as methyl 3-methoxyproplonate, ethyl 3-methoxypropionate, ethyl 3-ethoxypropionate and methyl 3-ethoxypropionate; alkyl 2-oxypropionates, such as methyl 2-oxypropionate, ethyl 2-oxypropionate and propyl 2-oxypropionate; alkyl 2-alkoxypropionates, such as methyl 2-methoxypropionate, ethyl 2-methoxypropionate, ethyl 2-ethoxyproplonate and methyl 2-ethoxypropionate; 2-oxy-2-methylpropionic acid esters, such as methyl 2-oxy-2-methylpropionate and ethyl 2-oxy-2-methylpropionate; alkyl monooxymonocarboxylates of alkyl 2-alkoxy-2-methylpropionates, such as methyl 2-methoxy-2-methylpropionate and ethyl 2-ethoxy-2-methylpropionate; esters, such as ethyl 2-hydroxypropionate, ethyl 2-hydroxy-2-methylpropionate, ethyl hydroxyacetate and methyl 2-hydroxy-3-methylbutanoate; ketonic acid esters, such as ethyl pyruvate; high-boiling solvents, such as N-methylformamide, N,N-dimethylformamide, N-methylformanilide, N-methylacetamide, N,N-dimethylacetamide, N-methylpyrrolidone, dimethylsulfoxide, benzyl ethyl ether, dihexyl ether, acetonylacetone, isophorone, caproic acid, caprilic acid, 1-octanol, 1-nonanol, benzyl alcohol, benzyl acetate, ethyl benzoate, diethyl oxalate, diethyl maleate, γ-butyrolactone, ethylene carbonate, propylene carbonate and phenyl cellosolve acetate; and the like, and combinations thereof.

Glycol ethers, such as ethylene glycol monoethyl ether; ethylene glycol alkyl ether acetates, such as ethyl cellosolve acetate; esters, such as ethyl 2-hydroxypropionate; diethylene glycols, such as diethylene glycol monomethyl ether; and propylene glycol alkylether acetates, such as propylene glycol methyl ether acetate and propylene glycol propyl ether acetate can provide good compatibility and reactivity with the copolymer.

The photosensitive resin composition of the present invention may optionally further comprise a silane coupling agent for improving the adhesion of the composition to a substrate. The silane coupling agent has a reactive substituent, such as a carboxyl group, a methacryloyl group, an isocyanate group or an epoxy group. Specific examples of the silane coupling agent include without limitation trimethoxysilylbenzoic acid, γ-methacryloxypropyltrimethoxysilane, vinyltriacetoxysilane, vinyltrimethoxysilane, γ-isocyanatopropyltriethoxysilane, γ-glycidoxypropyltrimethoxysilane, β-(3,4-epoxycylcohexyl)ethyltrimethoxysilane, and the like. These coupling agents may be used alone or in combination.

The photosensitive resin composition can include the coupling agent in an amount of about 0.001 to about 20 parts by weight, based on about 100 parts by weight of the alkali-soluble resin.

If necessary, a surfactant may optionally be blended with the photosensitive resin composition for improving the coatability and preventing freezing of the composition. Examples of the surfactant include without limitation commercially available fluorinated surfactants, under the trade marks BM-1000 and BM-1100 (BM Chemie), Megafac F142D, Megafac F172, Megafac F173 and Megafac F183 (Dainippon Ink & Chemicals, Inc.), Fluorad FC-135, FC-170C, FC-430 and FC-431 (Sumitomo 3M Co., Ltd.), Surflon S-112, S-113, S-131, S-141 and S-145 (Asahi Glass Co., Ltd.), and SH-28PA, SH-190, SH-193, SZ-6032 and SF-8428 (Toray Silicone). The photosensitive resin composition can include the surfactant in an amount of about 0.001 to about 5 parts by weight, based on about 100 parts by weight of the alkali-soluble resin.

If necessary, the photosensitive resin composition of the present invention may optionally further comprise one or more additives so long as the properties of the present invention are not impaired.

The photosensitive resin composition of the present invention can be used to form column spacers of a liquid crystal display device. The formation of column spacers using the photosensitive resin composition can be achieved by the following method.

### 1. Application and Formation of Coating Film

A solution of the photosensitive resin composition according to the present invention can be applied to an intended thickness (e.g., from about 2 to about 5 μm) to a pretreated substrate by spin coating, slit coating or roll coating or by using an applicator. The coated substrate is heated to about 70 to about 90° C. for about 1 to about 10 minutes to remove the solvent. As a result, a coating film is formed on the substrate.

### 2. Light Exposure

A predetermined patterned mask is disposed on the coating film. The coating film is irradiated with actinic rays of about 200 to about 500 nm through the mask to form the pattern on the coating film. Exemplary light sources for the irradiation can include without limitation a low-pressure mercury lamp, a high-pressure mercury lamp, an ultrahigh-pressure mercury lamp, a metal halide lamp or an argon gas laser. X-rays and electron beams may also be used for the irradiation.

The exposure dose may be varied depending upon the kinds of the respective components of the composition, contents thereof and the thickness of the dried film. If a high-pressure mercury lamp is used, the exposure dose is below about 500 mJ/cm² (as measured by a 365-nm sensor).

### 3. Development

The exposed coating film is developed using a developing solution to dissolve and remove unnecessary portions and leave the exposed portions. As a result, a pattern is formed on the substrate.

### 4. Post-Treatment

The developed coating film can be cured by heating and irradiation with actinic rays to impart heat resistance, light resistance, adhesiveness, crack resistance, chemical resistance, high strength and storage stability to the image pattern.

As a result, column spacers for a liquid crystal display device are formed. The column spacers can have a compressive displacement of about 0.6 to about 0.8 μm and an elastic recovery of about 80% or higher.

Hereinafter, the present invention will be explained in more detail with reference to the following examples. However, these examples are given for the purpose of illustration of the preferred embodiments of the present invention only, and are not intended to limit the scope of the invention.

### EXAMPLES

### Synthesis Example 1

The following compounds are placed in a separable flask equipped with a stirrer, a reflux condenser, a drying tube, a nitrogen introduction tube, a thermometer, a temperature-controllable circulator and the like:

(1) Methacrylic acid 15 g

### (2) Styrene 5 g

(3) Dicyclopentanyl methacrylate 40 g
(4) Glycidyl methacrylate 30 g
(5) Lauryl methacrylate 10 g
(6) 2,2′-Azobis(2,4-dimethylvaleronitrile) 10 g
(7) Propylene glycol monomethyl ether acetate 208.76 g

The separable flask is flushed with nitrogen to create a nitrogen atmosphere in the flask and immersed in an oil bath. The components are polymerized at a reaction temperature 70° C. for 3 hours with stirring to give an alkali-soluble resin (‘Copolymer 1’)) having a molecular weight (M_{w}) of 8,300.

### Synthesis Example 2

An alkali-soluble resin (‘Copolymer 2’) is prepared in the same manner as in Synthesis Example 1, except that the following compounds are used.

(1) Methacrylic acid 15 g

### (2) Styrene 5 g

(3) Dicyclopentanyl methacrylate 40 g
(4) Glycidyl methacrylate 30 g
(5) Stearyl methacrylate 10 g
(6) 2,2′-Azobis(2,4-dimethyl valeronitrile) 10 g
(7) Propylene glycol monomethyl ether acetate 208.76 g

The molecular weight (M_{w}) of the Copolymer 2 is measured to be 12,300.

### Example 1

A photosensitive resin composition is prepared using the Copolymer 1 prepared in Synthesis Example 1 and the other components shown in Table 1:

TABLE 1

| Component | | Content (g) |
|---|---|---|
| Alkali-soluble resin | Copolymer 1 | 15.0* |
| Reactive unsaturated | Dipentaerythritolhexaacrylate | 16.5 |
| compound | | |
| Photopolymerization | IGR 369 (Ciba-Geigy) | 4.0 |
| initiator | | |
| Solvent | Propylene glycol methyl ether | 63.71 |
| | acetate | |
| Additive | γ-Glycidoxyl propyl trimethoxy | 0.79 |
| | silane (S-510, Chisso) | |

*The amount of the Copolymer 1 was determined based on the solid content

### Example 2

A resin composition is prepared in the same manner as in Example 1, except that 15.0 g of the Copolymer 2 is used as the alkali-soluble resin.

### Comparative Example 1

A resin composition is prepared in the same manner as in Example 1, except that 15.0 g of butadiene/styrene/methacrylic acid/dicyclopentanyl methacrylate/glycidyl methacrylate (M_{w}=19,800, KRBP-3, Wako, Japan) is used as the alkali-soluble resin.

### Comparative Example 2

A resin composition is prepared in the same manner as in Example 1, except that 15.0 g of butadiene/styrene/methacrylic acid/dicyclopentanyl methacrylate/glycidyl methacrylate (M_{w}=26,500, KRBP-3, Wako, Japan) is used as the alkali-soluble resin.

Formation and Evaluation of Physical Properties of Spacer Patterns

### (1) Formation of Spacer Patterns

Each of the photosensitive resin compositions prepared in Examples 1 and 2 and Comparative Examples 1 and 2 is applied to a glass substrate using a spin coater and dried at 80° C. for 90 seconds to form a coating film. The coating film is irradiated with light of a wavelength of 365 nm at a dose of 100 mJ/cm² through a patterned mask. Subsequently, the exposed film is developed with a dilute aqueous solution of potassium hydroxide (1 wt %) at 23° C. for one minute and cleaned with pure water for one minute to remove unnecessary portions and leave a spacer pattern. The spacer pattern is cured by heating in an oven at 220° C. for 30 minutes to form a final column spacer pattern.

### (2) Evaluation of Physical Properties of Patterns

### (i) Measurement of Compressive Displacement and Elastic Recovery

Spacers are formed using each of the photosensitive resin compositions so as to have a thickness (T) of 3.5±0.2 μm and a pattern width (W) of 30±1 μm, which are determined as basic dimensions for the measurement of the mechanical properties, i.e. compressive displacement and elastic recovery, of the spacers. The compressive displacement and elastic recovery of the spacers are measured using a microhardness tester (H-100, Fischer GmbH, Germany) under the following conditions.

The patterns are pressurized using a planar indenter having a diameter of 50 μm. A load-unload process is employed to measure the compressive displacement and elastic recovery of the patterns. At this time, the patterns are pressurized under a test load of 5 gf at a loading speed of 0.45 gf/s for a holding time of 3 seconds.

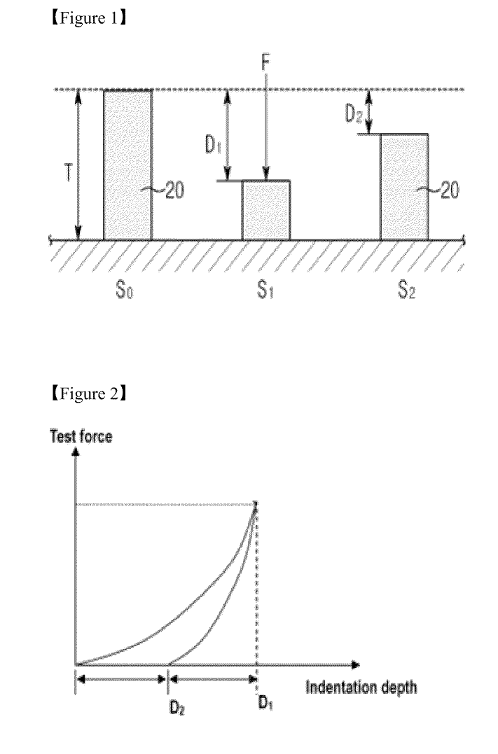

Referring to FIG. 1, an explanation of the compressive displacement and elastic recovery of a column spacer formed using the photosensitive resin composition of the present invention will be provided. A spacer 20 having a uniform thickness (T) is formed by patterning (S₀). The spacer is pressed using a substrate, such as an array substrate to decrease its thickness (S₁). At this time, the compressive displacement of the spacer refers to an indentation depth (D₁) of the pattern when a constant force is applied to the spacer, as shown in FIG. 1. When the compressive force (F) is removed, the thickness of the spacer is increased by a restoration force (S₂). The difference in thickness, i.e. between the initial thickness before the spacer is pressurized and the thickness after the spacer is restored, is expressed as D₂. This relationship is shown in FIG. 2.

The elastic recovery of the spacer can be understood as follows. As shown in FIG. 1, when a constant force is applied, the elastic recovery of the spacer refers to the ratio of a difference (D₁−D₂) between the indentation depth (D₁) and the restored depth (D₂) to the indentation depth (D₁). The compressive displacement and the elastic recovery of the spacer are summarized by the following equations:

Compressive displacement=D₁ (μm)

Elastic recovery=[(D₁−D₂)×100]/D₁

### (ii) Measurement of Residual Film Ratio

Each of the coating films is sequentially dried at 80° C. and 220° C. The residual film ratio of the coating film is defined as the ratio of a thickness measured after the coating film is dried at 80° C. to a thickness measured after the coating film is dried at 220° C.

The results for the physical properties of the column spacer patterns formed using the respective compositions are set forth in Table 2.

TABLE 2

| | Compressive | Elastic | Residual film |
|---|---|---|---|
| Example No. | displacement (μm) | recovery (%) | ratio (%) |
| Example 1 | 0.63 | 81.5 | 93 |
| Example 2 | 0.62 | 81.7 | 93 |
| Comparative | 0.53 | 77.5 | 92 |
| Example 1 | | | |
| Comparative | 0.48 | 79.9 | 92 |
| Example 2 | | | |

The results of Table 2 demonstrate that the spacers formed using the respective photosensitive resin compositions of the present invention showed higher compressive displacement, elastic recovery and residual film ratio than those formed using the conventional photosensitive resin compositions.

Many modifications and other embodiments of the invention will come to mind to one skilled in the art to which this invention pertains having the benefit of the teachings presented in the foregoing descriptions. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation, the scope of the invention being defined in the claims.

That which is claimed is:

1. A photosensitive resin composition for forming column spacers of a liquid crystal display device, the resin composition comprising [A] an alkali-soluble resin, [B] a reactive unsaturated compound, [C] a photopolymerization initiator and [D] a solvent, wherein the alkali-soluble resin [A] is a copolymer including structural units represented by Formulae 1 to 3: 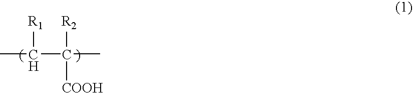
wherein R₁ and R₂ are each independently a hydrogen atom or a C₁-C₆ alkyl group; 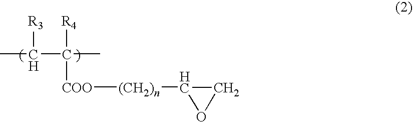
wherein R₃ and R₄ are each independently a hydrogen atom or a C₁-C₆ alkyl group and n is an integer from 1 to 10; and 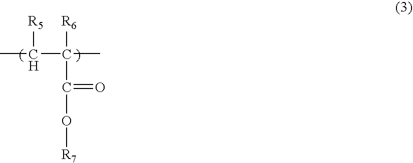
wherein R₅ and R₆ are each independently a hydrogen atom or a C₁-C₆ alkyl group and R₇ is a linear or branched C₆-C₃₀ alkyl group.

2. The photosensitive resin composition according to claim 1, wherein the alkali-soluble resin [A] includes about 5 to about 50% by weight of the structural unit of Formula 1, about 10 to about 70% by weight of the structural unit of Formula 2, and about 0.1 to about 30% by weight of the structural unit of Formula 3.

3. The photosensitive resin composition according to claim 1, wherein the composition comprises about 1 to about 50% by weight of the alkali-soluble resin [A], about 1 to about 50% by weight of the reactive unsaturated compound [B], about 0.1 to about 15% by weight of the photopolymerization initiator [C] and the balance of the solvent [D].

4. The photosensitive resin composition according to claim 1, wherein the alkali-soluble resin [A] further includes a structural unit represented by Formula 4 or 5 or a combination thereof: 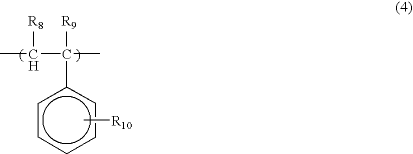
wherein R₈ and R₉ are each independently a hydrogen atom or a C₁-C₆ alkyl group and R₁₀ is a hydrogen atom, a C₁-C₄ alkyl group or a C₁-C₄ alkoxy group; or 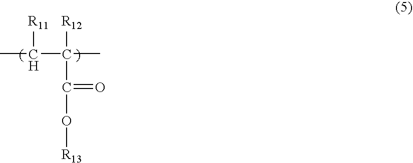
wherein R₁₁ and R₁₂ are each independently a hydrogen atom or a methyl group, and R₁₃ is a C₁-C₅ alkyl group or a C₅-C₁₂ cycloalkyl group which is unsubstituted or substituted with one or more methyl groups, C₁-C₄ oxyalkyl groups, or a combination thereof.

5. The photosensitive resin composition according to claim 4, wherein the structural unit of Formula 4 or 5 or a combination thereof is included in an amount of about 10 to about 70% by weight, based on the total weight of the alkali-soluble resin.

6. The photosensitive resin composition according to claim 1, further comprising about 0.001 to about 20 parts by weight of a silane coupling agent, based on about 100 parts by weight of the alkali-soluble resin [A].

7. The photosensitive resin composition according to claim 1, further comprising about 0.001 to about 5 parts by weight of a fluorinated surfactant, based on about 100 parts of the alkali-soluble resin [A].

8. A photosensitive resin composition for forming column spacers of a liquid crystal display device, the resin composition comprising an alkali-soluble resin, a reactive unsaturated compound, a photopolymerization initiator and a solvent wherein the alkali-soluble resin is a copolymer including about 1 to about 15% by weight of a structural unit represented by Formula 3, based on the total weight of the alkali-soluble resin: 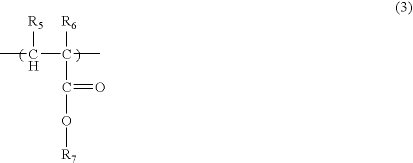
wherein R₅ and R₆ are each independently a hydrogen atom or a C₁-C₆ alkyl group and R₇ is a linear or branched C₆-C₃₀ alkyl group.

9. A method for forming column spacers of a liquid crystal display device, the method comprising the steps of:
(a) applying the photosensitive resin composition according to claim 1 to a thickness of about 2 to about 5 μm to a substrate to form a coating film;
(b) irradiating the coating film with actinic rays of a wavelength of about 200 to about 500 nm; and
(c) developing the exposed coating film using a developing solution to form a pattern.

10. A column spacer formed by the method according to claim 9.

11. The column spacer according to claim 10, wherein the column spacer has a compressive displacement of about 0.6 to about 0.8 μm and an elastic recovery of about 80% or higher.

12. A display device comprising the column spacer according to claim 10.
